(19) United States
(12) Patent Application Publication
(10) Pub. No.: US 2026/0145991 A1
(43) Pub. Date: May 28, 2026

(54) LITHIUM ALUMINOSILICATE GLASSES MADE FROM HIGH RECYCLED CONTENT

(71) Applicant: CORNING INCORPORATED, CORNING, NY (US)

(72) Inventors: Timothy Michael Gross, Painted Post, NY (US); Peter Joseph Lezzi, Corning, NY (US); Jingshi Wu, Painted Post, NY (US)

(21) Appl. No.: 19/358,683

(22) Filed: Oct. 15, 2025

Related U.S. Application Data
(60) Provisional application No. 63/725,220, filed on Nov. 26, 2024.

(51) Int. Cl. C03C 3/091; C03C 1/00; H05K 5/03

(52) U.S. Cl. CPC C03C 3/091; C03C 1/002; H05K 5/03

(57) ABSTRACT

A glass-based article is provided, comprising: greater than or equal to 45.0 mol % and less than or equal to 60.0 mol % SiO₂; greater than or equal to 10.0 mol % and less than or equal to 25.0 mol % Al₂O₃; greater than or equal to 2.0 mol % and less than or equal to 8.0 mol % CaO; greater than or equal to 2.0 mol % and less than or equal to 10.0 mol % B₂O₃; greater than or equal to 0.2 mol % and less than or equal to 3.0 mol % MgO; greater than or equal to 0.2 mol % and less than or equal to 1.0 mol % SrO; greater than or equal to 0.0 mol % and less than or equal to 15.0 mol % Li₂O; greater than or equal to 0.0 mol % and less than or equal to 10.0 mol % Na₂O; greater than or equal to 10.0 mol % and less than or equal to 25.0 mol % Li₂O+Na₂O; wherein the ratio CaO (mol %)/MgO (mol %) is greater than or equal to 2.

### CROSS REFERENCE TO RELATED APPLICATION

This application claims the benefit of priority under 35 U.S.C. § 119 of U.S. Provisional Application Ser. No. 63/725,220 filed on Nov. 26, 2024, the content of which is relied upon and incorporated herein by reference in its entirety.

### BACKGROUND

### Field

The present specification generally relates to lithium aluminosilicate glasses. More specifically, the present specification is directed to lithium-containing aluminosilicate glasses with high recycled content.

### Technical Background

There is currently a push to use less raw materials in all forms of manufacturing, including glass making. To achieve this goal, scrap pieces of glass that go unused during the glass-making process can be recycled by re-melting the scraps in a furnace with raw materials. And, glass may be taken from used products at the end of their useful life and recycled. Indeed, recycling scraps of soda-lime glass to make new soda-lime glass products has been done for years because recycling glasses can make manufacturing new glass products more sustainable and eco-friendly. For instance, it helps reduce pollution and waste; it saves energy used in manufacturing because cullet often melts at a lower temperature; it reduces air pollution and related water pollution that results from producing similar glasses; and it reduces the space in landfills by reducing disposed of cullet. Accordingly, a need exists for technically sophisticated glasses—such as strengthened aluminosilicate glasses—that can be made with recycled materials.

### SUMMARY

The present disclosure is directed to glass compositions having suitable strength and flexibilities for various applications.

In a 1^{st} aspect, a glass-based article is provided, comprising: greater than or equal to 45.0 mol % and less than or equal to 60.0 mol % SiO₂; greater than or equal to 10.0 mol % and less than or equal to 25.0 mol % Al₂O₃; greater than or equal to 2.0 mol % and less than or equal to 8.0 mol % CaO; greater than or equal to 2.0 mol % and less than or equal to 10.0 mol % B₂O₃; greater than or equal to 0.2 mol % and less than or equal to 3.0 mol % MgO; greater than or equal to 0.2 mol % and less than or equal to 1.0 mol % SrO; greater than or equal to 0.0 mol % and less than or equal to 15.0 mol % Li₂O; greater than or equal to 0.0 mol % and less than or equal to 10.0 mol % Na₂O; greater than or equal to 10.0 mol % and less than or equal to 25.0 mol % Li₂O+Na₂O; wherein the ratio CaO (mol %)/MgO (mol %) is greater than or equal to 2.

In a 2^{nd} aspect, the glass-based article of the first aspect further comprises: greater than or equal to 50.0 mol % and less than or equal to 58.0 mol % SiO₂.

In a 3^{rd} aspect, the glass-based article of any of the 1^{st} or 2^{nd} aspects further comprises: greater than or equal to 14.0 mol % and less than or equal to 23.0 mol % Al₂O₃.

In a 4^{th} aspect, the glass-based article of any of the 1^{st} through 3^{rd} aspects further comprises: greater than or equal to 3.0 mol % and less than or equal to 7.0 mol % CaO.

In a 5^{th} aspect, the glass-based article of any of the 1^{st} through 4^{th} aspects further comprises: greater than or equal to 4.0 mol % and less than or equal to 8.0 mol % B₂O₃.

In a 6^{th} aspect, the glass-based article of any of the 1^{st} through 5^{th} aspects further comprises: greater than or equal to 0.9 mol % and less than or equal to 1.8 mol % MgO.

In a 7^{th} aspect, the glass-based article of any of the 1^{st} through 6^{th} aspects further comprises: greater than or equal to 0.2 mol % and less than or equal to 0.5 mol % SrO;

In an 8^{th} aspect, the glass-based article of any of the 1^{st} through 7^{th} aspects further comprises: greater than or equal to 4.0 mol % and less than or equal to 12.0 mol % Li₂O;

In a 9^{th} aspect, the glass-based article of any of the 1^{st} through 8^{th} aspects further comprises: greater than or equal to 2.0 mol % and less than or equal to 9.0 mol % Na₂O;

In a 10^{th} aspect, the glass-based article of any of the 1^{st} through 9^{th} aspects further comprises: greater than or equal to 11.0 mol % and less than or equal to 15.0 mol % Li₂O+Na₂O.

In a 11^{th} aspect, for the glass-based article of any of the 1^{st} through 10^{th} aspects, the glass-based article has a K_{1C} fracture toughness as measured by a chevron notch short bar method of greater than or equal to 0.8.

In a 12^{th} aspect, for the glass-based article of any of the 1^{st} through 11^{th} aspects, the glass-based article has a liquidus viscosity of greater than or equal to 1000 poise.

In a 13^{th} aspect, for the glass-based article of any of the 1^{st} through 12^{th} aspects, the glass-based article has an anorthite liquidus phase.

In a 14^{th} aspect, for the glass-based article of any of the 1^{st} through 13^{th} aspects, the glass-based article is chemically strengthened and has a compressive stress of greater than or equal to 550.0 MPa.

In a 15^{th} aspect, for the glass-based article of any of the 1^{st} through 14^{th} aspects, the strengthened glass-based article has a maximum central tension of greater than or equal to 90.0 MPa.

In a 16^{th} aspect, for the glass-based article of any of the 1^{st} through 15^{th} aspects, the strengthened glass-based article has a depth of compression (DOC) greater than or equal to 160.0 microns.

In a 17^{th} aspect, for the glass-based article of any of the 1^{st} through 16^{th} aspects, the strengthened glass-based article has a Knoop Scratch threshold in the range of greater than or equal to 4.0 N to less than or equal to 14.0 N.

In an 18^{th} aspect, a process for making a glass-based material comprises:
creating a melt, the melt comprising:
   greater than or equal to 35.0 wt % and less than or equal to 75 wt % cullet;
   greater than or equal to 0.0 wt % and less than or equal to 26 wt % SiO₂;
   greater than or equal to 2.0 wt % and less than or equal to 15 wt % Na₂CO₃;
   greater than or equal to 10.0 wt % and less than or equal to 22.0 wt % Al₂O₃;
   greater than or equal to 4.0 wt % and less than or equal to 12.0 wt % Li₂CO₃;
processing the melt to form a glass-based material;
wherein the cullet comprises:
   greater than or equal to 64.0 mol % and less than or equal to 71.0 mol % SiO₂;
   greater than or equal to 9.0 mol % and less than or equal to 12.0 mol % Al₂O₃;
   greater than or equal to 6.0 mol % and less than or equal to 11.0 mol % CaO;
   greater than or equal to 7.0 mol % and less than or equal to 12.0 mol % B₂O₃;
   greater than or equal to 1.0 mol % and less than or equal to 3.0 mol % MgO;
   greater than or equal to 0.2 mol % and less than or equal to 2.0 mol % SrO;
and
wherein the glass-based material comprises the composition of the glass-based article of any of aspects 1 through 17.

In a 19^{th} aspect, for aspect 18, processing the melt comprises forming the melt into a sheet using a thin sheet rolling process.

In a 20^{th} aspect, a consumer electronic device comprises: a housing having a front surface, a back surface, and side surfaces; electrical components provided at least partially with the housing, the electrical components including at least a controller, a memory, and a display, the display being provided at or adjacent the front surface of the housing; and a glass-based article, according to any of aspects 1 through 17, disposed over the display.

Additional features and advantages will be set forth in the detailed description which follows, and in part will be readily apparent to those skilled in the art from that description or recognized by practicing the embodiments described herein, including the detailed description which follows, the claims, as well as the appended drawings.

It is to be understood that both the foregoing general description and the following detailed description describe various embodiments and are intended to provide an overview or framework for understanding the nature and character of the claimed subject matter. The accompanying drawings are included to provide a further understanding of the various embodiments, and are incorporated into and constitute a part of this specification. The drawings illustrate the various embodiments described herein, and together with the description serve to explain the principles and operations of the claimed subject matter.

### BRIEF DESCRIPTION OF THE DRAWINGS

FIG. 1 schematically depicts a cross section of a glass having compressive stress layers on surfaces thereof according to embodiments disclosed and described herein;

FIG. 2A schematically depicts an exemplary electronic device incorporating a glass article according to any of the glass articles disclosed and described herein;

FIG. 2B schematically depicts an exemplary electronic device incorporating a glass article according to any of the glass articles disclosed and described herein; and

FIG. 3 is a ternary phase diagram for SiO₂, CaO and MgO at 25 wt % Al₂O₃.

FIG. 4 is a ternary phase diagram for SiO₂, CaO and MgO at 35 wt % Al₂O₃.

FIG. 5 is a diagram of a two-slope stress profile, with key parameters labeled.

FIG. 6 is a graph showing the stress profile for Composition 10 after ion exchange.

FIG. 7 is a graph showing the stress profile for Composition 11 after ion exchange.

FIG. 8 is a graph showing the stress profile for Composition 12 after ion exchange.

FIG. 9 is a graph showing the stress profile for Composition 19 after ion exchange.

FIG. 10 is a graph showing the stress profile for Composition 20 after ion exchange.

FIG. 11 is a graph showing the stress profile for Composition 21 after ion exchange.

### DETAILED DESCRIPTION

Commercial alkali aluminosilicate glasses are usually not made from recycled glass. The precision required to make compositions that will have all of the desired properties and still be able to be strengthened does not lend itself to requiring that a significant part of the input materials have the compositions of the cullet. Moreover, when using cullet it can be difficult to individually to control the amount of one or more oxides without also impacting the amounts of other components in the glass composition. And, recycled cullet from a different product by its nature includes different amounts of materials than desired, often including some material components that are not desired at all and may impact various material properties and attributes. Accordingly, it is extremely difficult to be able to balance all of the glass components to get the precise composition required to make a glass that has desired properties such as liquidus so that it is formable by desired methods (such as thin sheet rolling) and also can be adequately strengthened. For instance, the magnitude of surface compression as well as the depth of compressive stress layer (DOL) play an important role in creating stronger glasses. Taking all of these attributes into consideration while being restricted to compositions of glass cullet results in a unique glass composition that provides a balance of formability and strength.

There is a great deal of glass cullet available for recycling having a composition in the ranges:
greater than or equal to 64.0 mol % and less than or equal to 71.0 mol % SiO₂;
greater than or equal to 9.0 mol % and less than or equal to 12.0 mol % Al₂O₃;
greater than or equal to 6.0 mol % and less than or equal to 11.0 mol % CaO;
greater than or equal to 7.0 mol % and less than or equal to 12.0 mol % B₂O₃;
greater than or equal to 1.0 mol % and less than or equal to 3.0 mol % MgO;
greater than or equal to 0.2 mol % and less than or equal to 2.0 mol % SrO.
   Notably, this cullet composition contains very little or no alkali metal, which are widely used for ion exchange in the mobile consumer electronics industry. And, the cullet composition includes SrO, which is often absent from premium high performance glass-based materials used in the mobile consumer electronics industry. Nevertheless, it has been discovered that, with the addition of appropriately selected raw materials, an ion-exchangeable composition with favorable performance attributes can be achieved, while using a reasonably high percentage of recycled cullet in the melt.

Reference will now be made in detail to alkali aluminosilicate glasses according to various embodiments. The physical properties of alkali aluminosilicate glasses generally may be related to the glass composition and structure.

Alkali aluminosilicate glasses used for mobile consumer electronics are often tailored to have good ion exchange ability, and chemical strengthening processes have been used to achieve high strength and high toughness properties in alkali aluminosilicate glasses. Lithium aluminosilicate glasses are highly ion exchangeable glasses with good glass formability and quality. The substitution of Al₂O₃ into the silicate glass network increases the interdiffusivity of monovalent cations during ion exchange. The diffusivity, as measured in diffusion coefficients, is one of the key factors in determining the ion-exchange ability in alkali aluminosilicate glasses, which depends on the glass framework and ion sizes. By chemical strengthening in a molten salt bath (e.g., KNO₃), glasses with high strength and high toughness can be achieved.

Described herein are alkali aluminosilicate glass compositions that may be ion-exchanged to achieve high good compressive stress (CS) and a good depth of compression (DOC) in a commercially reasonable IOX bath and time frame. In addition, glass compositions according to embodiments disclosed and described herein have properties that allow glass sheets to be formed from the glass composition using thin sheet rolling, as described, for example, in U.S. Pat. Nos. 10,899,650 and 8,713,972.

In embodiments of glass-based compositions described herein, the concentration of constituent components (e.g., SiO₂, Al₂O₃, and the like) are given in mole percent (mol %) on an oxide basis, unless otherwise specified. Components of the alkali aluminosilicate glass composition according to embodiments are discussed individually below. It should be understood that any of the variously recited ranges of one component may be combined with the any of the variously recited ranges for any other component.

Materials used as input for a melt are typically in the form of powders, granulated material, etc. The relative amount of each material put into the melt is usually determined by weighing on a scale. As such, melt components are described herein in terms of wt %. And, it is easy to think of these powders/grains in terms of relative weight. The material components of a glass-based material, on the other hand, are integrated into the structure of the material and cannot be separated into separate piles for weighing on a scale. The amounts of these materials are measured in various ways for the compositions described herein. Boron is measured by Laser Ablation Inductively Coupled Plasma Mass Spectrometry. Li is measured by Flame Emission Spectrometry. For all other components of glass-based materials, unless otherwise specified, the amount of material is measured by x-ray fluorescent spectrometry diffraction. This includes cullet material composition as well as the composition of a final article. Many scientists find it easier to think of material components in a glass-based material in terms of mol %, because it correlates to the relative number of atoms present and helps with visualization of material structure. So, the amount of material present in a glass-based material are provided in mol % herein. So, for example, in the 18^{th} Aspect described in the Summary, the components of the melt are provided as wt %, and the components of the cullet and glass-based article are provided as mol %, consistent with the designations used in the daily work of the scientists involved here.

It is occurring with some frequency in the industry for the total percentage of material components in a glass-based material to add up to a number somewhat different from 100 wt % or 100 mol %. When this occurs, and consistent with industry practice, the numbers may be “normalized” by calculating the total percentage as measured or provided in a table, and multiplying the amount of each material by a “normalization factor” that is:

$$100 \% / calculated total \%$$

This will result in percentages that add up to 100%.

### Components and Amounts

According to embodiments, the main glass-forming component is silica (SiO₂), which is the largest constituent of the composition and, as such, is the primary constituent of the resulting glass network. Without being bound to theory, SiO₂ enhances the chemical durability of the glass and, in particular, the resistance of the glass composition to decomposition in acid and the resistance of the glass composition to decomposition in water. If the content of SiO₂ is too low, the chemical durability and chemical resistance of the glass may be reduced and the glass may be susceptible to corrosion. Accordingly, a high SiO₂ concentration is generally desired in embodiments. However, if the content of SiO₂ is too high, the formability of the glass may be diminished as higher concentrations of SiO₂ may increase the difficulty of melting the glass which, in turn, adversely impacts the formability of the glass.

In embodiments, the glass composition generally comprises SiO₂ in an amount greater than or equal to 45.0 mol % and less than or equal to 60.0 mol %. The amount of SiO₂ may be 45.0 mol %, 46.0 mol %, 47.0 mol %, 48.0 mol %, 49.0 mol %, 50.0 mol %, 51.0 mol %, 52.0 mol %, 53.0 mol %, 54.0 mol %, 55.0 mol %, 56.0 mol %, 57.0 mol %, 58.0 mol %, 59.0 mol %, 60.0 mol %, and any range having any two of these values as endpoints. In preferred embodiments, the glass composition comprises SiO₂ in amounts greater than or equal to 45.0 mol % and less than or equal to 60 mol %; greater than or equal to 50.0 mol % and less than or equal to 58 mol %; or greater than or equal to 53.0 mol % and less than or equal to 57.0 mol %.

The glass composition of embodiments may further comprise Al₂O₃. Al₂O₃ may serve as a glass network former, similar to SiO₂. Al₂O₃ may increase the viscosity of the glass composition due to its tetrahedral coordination in a glass melt formed from a properly designed glass composition, decreasing the formability of the glass composition when the amount of Al₂O₃ is too high. However, when the concentration of Al₂O₃ is balanced against the concentration of SiO₂ and the concentration of alkali oxides in the glass composition, Al₂O₃ can reduce the liquidus temperature of the glass melt, thereby enhancing the liquidus viscosity and improving the compatibility of the glass composition with certain forming processes, or decrease such compatibility, depending on the desired liquidus viscosity.

In embodiments, the glass composition generally comprises Al₂O₃ in a concentration of greater than or equal to 10.0 mol % and less than or equal to 25.0 mol %. The amount of Al₂O₃ may be 10.0 mol %, 11.0 mol %, 12.0 mol %, 13.0 mol %, 14.0 mol %, 15.0 mol %, 16.0 mol %, 17.0 mol %, 18.0 mol %, 19.0 mol %, 20.0 mol %, 21.0 mol %, 22.0 mol %, 23.0 mol %, 24.0 mol %, 25.0 mol %, and any range having any two of these values as endpoints. In preferred embodiments, the glass composition comprises Al₂O₃ in amounts greater than or equal to 10.0 mol % and less than or equal to 25.0 mol %; greater than or equal to 12.0 mol % and less than or equal to 24.0 mol %; or greater than or equal to 14.0 mol % and less than or equal to 23.0 mol %.

Glass compositions of embodiments include calcium oxide (CaO). CaO is a flux which may be added to glass compositions to reduce the viscosity of the glass at a given temperature, thereby improving the quality and formability of the glass. Compared with Na₂O, CaO may reduce CTE of the glass. However, too much CaO in a glass composition may decrease the rate of ion exchange in the resultant glass and cause phase separation in high B₂O₃ containing glass. Accordingly, the content of calcium oxide is limited in embodiments.

In embodiments, the glass composition generally comprises CaO in a concentration of greater than or equal to 2.0 mol % and less than or equal to 8.0 mol %. The amount of CaO may be 2.0 mol %, 3.0 mol %, 4.0 mol %, 5.0 mol %, 6.0 mol %, 7.0 mol %, 8.0 mol %, and any range having any two of these values as endpoints. In preferred embodiments, the glass composition comprises CaO in amounts greater than or equal to 2.0 mol % and less than or equal to 8.0 mol %; greater than or equal to 3.0 mol % and less than or equal to 7.0 mol %; or greater than or equal to 4.0 mol % and less than or equal to 6.0 mol %.

In embodiments, the glass composition may include boron oxide (B₂O₃). Boron oxide is a flux which may be added to glass compositions to reduce the viscosity of the glass at a given temperature (e.g., the temperature corresponding to the viscosity of 200 poise or a 200 P temperature, at which glass is melted), thereby improving the quality and formability of the glass. The presence of B₂O₃ may also improve scratch resistance of the glass made from the glass composition.

In embodiments, the glass composition generally comprises B₂O₃ in a concentration of greater than or equal to 2.0 mol % and less than or equal to 10.0 mol %. The amount of B₂O₃ may be 2.0 mol %, 3.0 mol %, 4.0 mol %, 5.0 mol %, 6.0 mol %, 7.0 mol %, 8.0 mol %, 9.0 mol %, 10.0 mol %, and any range having any two of these values as endpoints. In preferred embodiments, the glass composition comprises B₂O₃ in amounts greater than or equal to 2.0 mol % and less than or equal to 10.0 mol %; greater than or equal to 3.0 mol % and less than or equal to 9.0 mol %; or greater than or equal to 4.0 mol % and less than or equal to 8.0 mol %.

Glass composition of embodiments may include magnesia (MgO). Magnesia may provide greater increasing the elastic moduli than other divalent metal oxides without providing adverse increase to the density. However, when MgO is added in a high concentration, it can increase the liquidus temperature and cause precipitation of refractory minerals, such as spinel (MgAl₂O₄), forsterite (Mg₂SiO₄) and others, from the glass forming melts at high temperatures. Also, at high concentrations, MgO can slow down the ion exchange. Accordingly, the content of magnesia is limited in embodiments.

In embodiments, the glass composition generally comprises MgO in a concentration of greater than or equal to 0.2 mol % and less than or equal to 3.0 mol %. The amount of MgO may be 0.2 mol %, 0.5 mol %, 0.9 mol %, 1.0 mol %, 1.5 mol %, 1.8 mol %, 2.0 mol %, 2.5 mol %, 3.0 mol %, and any range having any two of these values as endpoints. In preferred embodiments, the glass composition comprises MgO in amounts greater than or equal to 0.2 mol % and less than or equal to 3.0 mol %; greater than or equal to 0.5 mol % and less than or equal to 1.9 mol %; or greater than or equal to 0.9 mol % and less than or equal to 2.5 mol %.

Glass composition of embodiments may include magnesia (SrO). SrO is not particularly desirable as a component for ion-exchangeable glass used for mobile consumer electronics. But, it is present in the cullet used in the melt in the embodiments described herein, due to a desire to recycle such cullet. Notwithstanding the presence of SrO, the glass compositions described herein have reasonably good attributes.

In embodiments, the glass composition generally comprises SrO in a concentration of greater than or equal to 0.2 mol % and less than or equal to 1.0 mol %. The amount of SrO may be 0.2 mol %, 0.3 mol %, 0.4 mol %, 0.5 mol %, 0.6 mol %, 0.7 mol %, 0.8 mol %, 0.9 mol %, 1.0 mol %, and any range having any two of these values as endpoints. In preferred embodiments, the glass composition comprises SrO in amounts greater than or equal to 0.2 mol % and less than or equal to 1.0 mol %; greater than or equal to 0.2 mol % and less than or equal to 0.8 mol %; or greater than or equal to 0.2 mol % and less than or equal to 0.5 mol %.

According to embodiments, the glass composition may also comprise alkali metal oxides, such as Na₂O and Li₂O, for example. The combination of these alkali metal oxides (e.g. Na₂O+Li₂O) may also be referred to as R₂O. A glass composition having the right amount of alkali metal oxides, and particularly Na₂O and Li₂O, can achieve a deep depth of compression (DOC) and/or depth of layer (DOL), and a high surface compressive stress (CS) may be obtained. In addition, alkali metal oxides, and especially Li₂O, provide short ion-exchange time with high DOC and high central tension (CT).

In embodiments, the glass composition generally comprises Na₂O+Li₂O in a concentration of greater than or equal to 10.0 mol % and less than or equal to 25.0 mol %. The amount of Na₂O+Li₂O may be 11.0 mol %, 12.0 mol %, 13.0 mol %, 14.0 mol %, 15.0 mol %, 16.0 mol %, 17.0 mol %, 18.0 mol %, 19.0 mol %, 20.0 mol %, 21.0 mol %, 22.0 mol %, 23.0 mol %, 24.0 mol %, 25.0 mol %, and any range having any two of these values as endpoints. In preferred embodiments, the glass composition comprises Na₂O+Li₂O in amounts greater than or equal to 10.0 mol % and less than or equal to 25.0 mol %; greater than or equal to 10.0 mol % and less than or equal to 20.0 mol %; or greater than or equal to 11.0 mol % and less than or equal to 15.0 mol %.

In embodiments, the glass compositions comprises sodium oxide (Na₂O). The amount of Na₂O in the glass compositions also relates to the ion exchangeability of the glass made from the glass compositions. Specifically, the presence of Na₂O in the glass compositions may increase the ion exchange rate during ion exchange strengthening of the glass by increasing the diffusivity of Na ions through the glass matrix. Also, Na₂O may suppress the crystallization of alumina containing species, such as spodumene, mullite and corundum and, therefore, decrease the liquidus temperature and increase the liquidus viscosity. However, increasing the Na₂O amount in the glass compositions may increase CTE and worsen the mechanical properties of glass since it decreases the elastic modulus and the fracture toughness, and/or decrease the annealing and strain points of glass. Accordingly, it is desirable in embodiments to limit the amount of Na₂O present in the glass compositions.

In embodiments, the glass composition generally comprises Na₂O in a concentration of greater than or equal to 0.0 mol % and less than or equal to 10.0 mol %. The amount of Na₂O may be 1.0 mol %, 2.0 mol %, 3.0 mol %, 4.0 mol %, 5.0 mol %, 6.0 mol %, 7.0 mol %, 8.0 mol %, 9.0 mol %, 10.0 mol %, and any range having any two of these values as endpoints. In preferred embodiments, the glass composition comprises Na₂O in amounts greater than or equal to 0.0 mol % and less than or equal to 10.0 mol %; greater than or equal to 2.0 mol % and less than or equal to 9.0 mol %; or greater than or equal to 3.0 mol % and less than or equal to 8.0 mol %.

In one or more embodiments, the glass composition may include lithium oxide (Li₂O). Without being bound by theory, adding Li₂O to a glass composition makes a glass suitable to high-performance ion exchange of lithium ion (Li) for a larger alkali metal ion, such as sodium ion (Na). Since Li is very small (ionic radius is 0.06 nm), the Li in the glass can be ion-exchanged very quickly in Na containing salt bath, and allow to generate compressive stress in short time, and thereby generating a deep DOC in a short time. However, too much Li₂O in the glass can lower glass viscosity and raise glass liquidus temperature, therefore lower the glass liquidus viscosity and cause difficulty for mass production. To achieve good balance between stress profile and ability for manufacturing, it is desirable in embodiments to limit the amount of Li₂O present in the glass compositions.

In embodiments, the glass composition generally comprises Li₂O in a concentration of greater than or equal to 0.0 mol % and less than or equal to 15.0 mol %. The amount of Li₂O may be 1.0 mol %, 2.0 mol %, 3.0 mol %, 4.0 mol %, 5.0 mol %, 6.0 mol %, 7.0 mol %, 8.0 mol %, 9.0 mol %, 10.0 mol %, 11.0 mol %, 12.0 mol %, 13.0 mol %, 14.0 mol %, 15.0 mol %, and any range having any two of these values as endpoints. In preferred embodiments, the glass composition comprises Li₂O in amounts greater than or equal to 0.0 mol % and less than or equal to 15.0 mol %; greater than or equal to 3.0 mol % and less than or equal to 13.0 mol %; or greater than or equal to 4.0 mol % and less than or equal to 12.0 mol %.

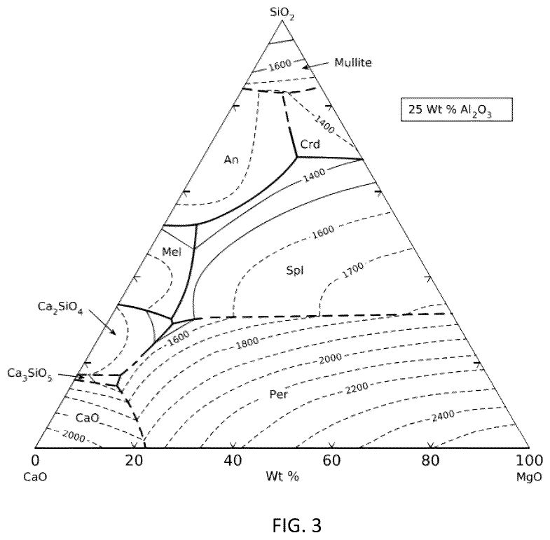

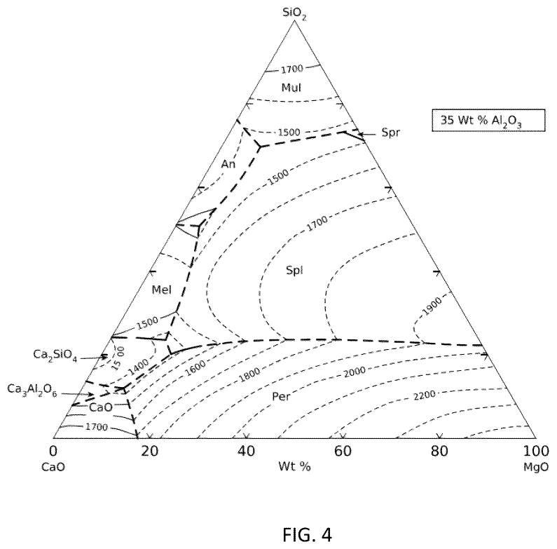

In one or more embodiments, the ratio CaO (mol %)/MgO (mol %) is greater than or equal to 2. FIG. 3 and FIG. 4 show ternary phase diagrams for the CaO, SiO₂, MgO system with different amounts of Al₂O₃. The phase diagrams are in wt %. The exemplary compositions provided herein, when converted to wt %, have Al₂O₃ in amounts roughly between 23 wt % and 35 wt %, so these phase diagrams are relevant.

Liquidus temperature refers to the temperature above which a glass-forming material is completely liquid. It is a boundary on a phase diagram (the contours in FIG. 3 and FIG. 4), indicating the highest temperature at which solid phases can coexist with the liquid phase. In manufacturing, preferable conditions include lower liquidus temperatures and a liquidus phase that can be re-melted with ease. For instance, the melting temperature for anorthite is 1553° C., in contrast to spinel which melts at a significantly higher temperature of 2130° C. The phase diagrams of FIG. 3 and FIG. 4 below suggests that maintaining a CaO/MgO ratio above 3 (calculated in wt %, which is approximately equivalent to a ratio of 2 when calculated in mol %) increases the likelihood of the liquidus phase being anorthite (An). Conversely, keeping the CaO/MgO ratio under 3 (in wt %), which implies a higher concentration of MgO, makes the liquidus phase more likely to be spinel. Therefore, to favor the formation of anorthite, it is desirable to maintain the Ca/MgO ratio above 2 when calculated in mole percentage.

### Properties and Attributes—Measurement Definitions

Physical properties of alkali aluminosilicate glass compositions as disclosed and described herein will now be discussed.

The terms “glass-based article” and “glass-based substrates” are used to include any object made wholly or partly of glass, including glass-ceramics (including an amorphous phase and a crystalline phase). Laminated glass-based articles include laminates of glass and non-glass materials, for example laminates of glass and crystalline materials. Glass-based substrates according to one or more embodiments can be selected from alkali-aluminosilicate glass, alkali-containing borosilicate glass, alkali-containing aluminoborosilicate glass, and alkali-containing phosphosilicate glass.

A “base composition” is a chemical make-up of a substrate prior to any ion exchange (IOX) treatment. That is, the base composition is undoped by any ions from IOX. A composition at the center of a glass-based article that has been IOX treated is typically the same as the base composition when IOX treatment conditions are such that ions supplied for IOX do not diffuse into the center of the substrate. In one or more embodiments, a composition at the center of the glass article comprises the base composition.

The density of the glass compositions was determined using the buoyancy method of ASTM C693-93 (2013).

Refractive Index was measured on a B&L Low Range Refractometer with 1.698 index oil and a Sodium arc lamp. Prior to measurement, the samples were cleaned using a TX® 609 Technicloth® wiper dampened with HPLC grade reagent alcohol and wiped across the flat & polished edge. Samples consisted of 10 mm×20 mm pieces having one polished flat and one end polished 90° to the flat. The samples were measured for refractive index at 589.3 nm. The Bausch & Lomb Precision Refractometer measures the refractive index of a material by measuring the critical angle. A NIST 1820 refractive index glass standard was measured before the sample set. Sample values were compared with the value of the standard and the offset was used to correct sample values with OPL's B&L Low Range 33-45-02 Conversion worksheet. The corrected values are given in this report. Three pieces of each sample were provided. Each piece was measured once, and the values averaged.

The Poisson's ratio (v), the Young's modulus (E), and the shear modulus (G) of the glass compositions were measured by a resonant ultrasonic spectroscopy technique of the general type set forth in ASTM E2001-13. titled “Standard Guide for Resonant Ultrasound Spectroscopy for Defect Detection in Both Metallic and Non-metallic Parts.”

Glass compositions according to embodiments have a high fracture toughness. Without being bound by any particular theory, the high fracture toughness may impart improved drop performance to the glass compositions. The fracture toughness refers to the KIC value, and is measured by the chevron notched short bar method. The chevron notched short bar (CNSB) method utilized to measure the K_{1C} value is disclosed in Reddy, K. P. R. et al, “Fracture Toughness Measurement of Glass and Ceramic Materials Using Chevron-Notched Specimens,” J. Am. Ceram. Soc., 71 [6], C-310-C-313 (1988) except that Y*m is calculated using equation 5 of Bubsey, R. T. et al., “Closed-Form Expressions for Crack-Mouth Displacement and Stress Intensity Factors for Chevron-Notched Short Bar and Short Rod Specimens Based on Experimental Compliance Measurements,” NASA Technical Memorandum 83796, pp. 1-30 (October 1992). Fracture toughness is measured on a non-strengthened glass article, such as measuring the KIC value prior to ion exchange (IOX) treatment of the glass article, thereby representing a feature of a glass substrate prior to IOX. The fracture toughness test methods described herein are not suitable for glasses that have been exposed to IOX treatment. The measurements on corresponding underlying glass substrates (without IOX treatment), nonetheless, provide valuable information about the IOX′d glass properties. Accordingly, the fracture toughness of an IOX′d article is measured on an otherwise identical article that has not been IOX′d. In most IOX articles, the ion exchange does not significantly affect the composition at the center of the article, farthest away from any surface. Thus, the composition of the pre-IOX article may be determined by looking at the composition at the center of an IOX article. Unless otherwise specified, the CSNB method is used to measure fracture toughness values described herein, and the units are MPa(m)^{1/2}.

The term “strain point,” as used herein, refers to the temperature at which the viscosity of the glass composition is 1×10^{14.68} poise. The strain point of the glass compositions was determined using the fiber elongation method of ASTM C336-71 (2015).

The term “annealing point,” as used herein, refers to the temperature at which the viscosity of the glass composition is 1×10^{13.18} poise. The annealing point of the glass compositions was determined using the fiber elongation method of ASTM C336-71 (2015).

The term “softening point,” as used herein, refers to the temperature at which the viscosity of the glass composition is 1×10^{7.6} poise. The softening point of the glass compositions was determined using the fiber elongation method of ASTM C338-93 (2008).

As used herein, the term “liquidus viscosity” refers to the viscosity of a molten glass at the liquidus temperature, wherein the “liquidus temperature” refers to the temperature at which crystals first appear as a molten glass cools down from the melting temperature, or the temperature at which the very last crystals melt away as temperature is increased from room temperature. Unless specified otherwise, a liquidus viscosity value disclosed in this application is determined by the following method. First, the liquidus temperature of the glass is measured in accordance with ASTM C829-81 (2015). titled “Standard Practice for Measurement of Liquidus Temperature of Glass by the Gradient Furnace Method.” Next, the viscosity of the glass above the softening point is measured in accordance with ASTM C965-96 (2012), titled “Standard Practice for Measuring Viscosity of Glass Above the Softening Point”. The term “Vogel-Fulcher-Tamman (‘VFT’) relation,” as used herein, described the temperature dependence of the viscosity and is represented by the following equation log η=A+B/(T−T₀), where η is viscosity. To determine VFT A, VFT B, and VFT T₀, the viscosity of the glass composition is measured over a given temperature range. The raw data of viscosity versus temperature is then fit with the VFT equation by least-squares fitting to obtain A, B, and T₀. With these values, a viscosity point (e.g., 200 P Temperature, 35000 P Temperature, and 200000 P Temperature) at any temperature above softening point may be calculated. Unless otherwise specified, the liquidus viscosity and temperature of a glass composition or article is measured before the composition or article is subjected to any ion-exchange process or any other strengthening process. In particular, the liquidus viscosity and temperature of a glass composition or article is measured before the composition or article is exposed to an ion-exchange solution, for example before being immersed in an ion-exchange solution. Where an ion-exchanged article is described as having a liquidus viscosity, the reference is to the liquidus viscosity of the article prior to ion exchange. The pre-ion exchange composition may be determined by looking at the composition at the center of the article.

Unless otherwise specified, glass viscosity is measured by the rotating crucible method according to ASTM C965-96 (2017).

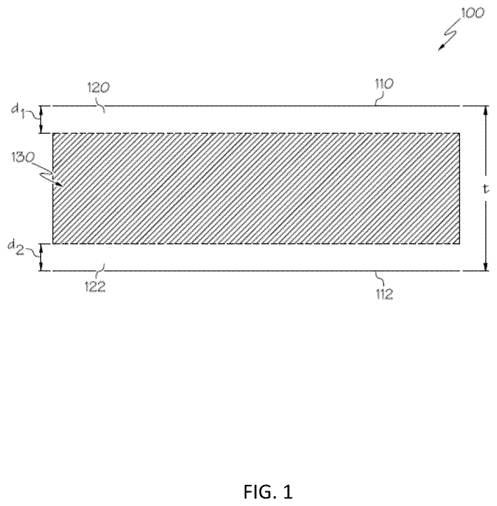

As mentioned above, in embodiments, the alkali aluminosilicate glass compositions can be strengthened, such as by ion exchange, making a glass that is damage resistant for applications such as, but not limited to, cover glasses and digital screens. With reference to FIG. 1, glass-based article 100 having a thickness/has a first region under compressive stress (e.g., first and second compressive layers 120, 122 in FIG. 1). First compressive layer 120 extends a distance d₁ from surface 110 to the DOC. Second compressive layer 122 extends a distance d₂ from surface 120 to the DOC. Central region 130 is under a tensile stress or central tension CT extending from the depth of compression into the central or interior region of the glass.

The term “single ion exchange process,” as used herein, refers to a process in which the glass composition is exposed to a single ion exchange solution, such as a KNO₃ or NaNO₃ molten salt bath.

The term “double ion exchange process,” as used herein, refers to a process in which the glass composition is exposed to a first ion exchange solution and a second ion exchange solution.

The term “multiple ion exchange process,” as used herein, refers to a process in which the glass composition is exposed to three or more ion exchange solutions.

The term “depth of compression” (DOC), as used herein, refers to the depth at which the stress crosses from a positive (compressive) stress to a negative (tensile) stress and thus exhibits a stress value of zero.

The term “depth of layer” (DOL), as used herein, refers to the depth within a glass-based article (i.e., the distance from a surface of the glass-based article to its interior region) at which an ion of a metal oxide or alkali metal oxide (e.g., the metal ion or alkali metal ion) diffuses into the glass-based article where the concentration of the ion reaches a minimum value, as determined by Glow Discharge-Optical Emission Spectroscopy (GD-OES)). Unless otherwise specified, the DOL is given as the depth of exchange of the slowest-diffusing ion introduced by an ion exchange (IOX) process.

A non-zero metal oxide concentration that varies from the first surface to a depth of layer (DOL) with respect to the metal oxide or that varies along at least a substantial portion of the article thickness (t) indicates that a stress has been generated in the article as a result of ion exchange. The variation in metal oxide concentration may be referred to herein as a metal oxide concentration gradient. The metal oxide that is non-zero in concentration and varies from the first surface to a DOL or along a portion of the thickness may be described as generating a stress in the glass-based article. The concentration gradient or variation of metal oxides is created by chemically strengthening a glass-based substrate in which a plurality of first metal ions in the glass-based substrate is exchanged with a plurality of second metal ions.

According to the convention normally used in the art, compression or compressive stress is expressed as a negative (<0) stress and tension or tensile stress is expressed as a positive (>0) stress. Throughout this description, however, CS is expressed as a positive or absolute value—i.e., as recited herein, CS=|CS|. The compressive stress (CS) has a maximum at or near the surface of the glass, and the CS varies with distance d from the surface according to a function.

“Peak compressive stress,” as used herein, refers to the highest compressive stress (“CS”) value measured within a compressive stress region. The CS often has a maximum at the surface of the glass, and the CS varies with distance d from the surface according to a function. Referring again to FIG. 1, a first segment 120 extends from first surface 110 to a depth d1 and a second segment 122 extends from second surface 112 to a depth d2. Together, these segments define a surface compression or surface CS of glass 100.

Compressive stress (CS) and depth of layer (DOL) are measured by surface stress meter (FSM) using commercially available instruments such as the FSM-6000, manufactured by Orihara Industrial Co., Ltd. (Japan). Surface stress measurements rely upon the accurate measurement of the stress optical coefficient (SOC), which is related to the birefringence of the glass. SOC in turn is measured according to Procedure C (Glass Disc Method) described in ASTM standard C770-16, entitled “Standard Test Method for Measurement of Glass Stress-Optical Coefficient,” the contents of which are incorporated herein by reference in their entirety.

The maximum central tension (CT) or peak tension (PT) and stress retention values are measured using a scattered light polariscope (SCALP) technique known in the art. The Refracted near-field (RNF) method or SCALP may be used to measure the stress profile and the depth of compression (DOC). When the RNF method is utilized to measure the stress profile, the maximum CT value provided by SCALP is utilized in the RNF method. In particular, the stress profile measured by RNF is force balanced and calibrated to the maximum CT value provided by a SCALP measurement. The RNF method is described in U.S. Pat. No. 8,854,623, entitled “Systems and methods for measuring a profile characteristic of a glass sample”, which is incorporated herein by reference in its entirety. In particular, the RNF method includes placing the glass article adjacent to a reference block, generating a polarization-switched light beam that is switched between orthogonal polarizations at a rate of from 1 Hz to 50 Hz, measuring an amount of power in the polarization-switched light beam and generating a polarization-switched reference signal, wherein the measured amounts of power in each of the orthogonal polarizations are within 50% of each other. The method further includes transmitting the polarization-switched light beam through the glass sample and reference block for different depths into the glass sample, then relaying the transmitted polarization-switched light beam to a signal photodetector using a relay optical system, with the signal photodetector generating a polarization-switched detector signal. The method also includes dividing the detector signal by the reference signal to form a normalized detector signal and determining the profile characteristic of the glass sample from the normalized detector signal.

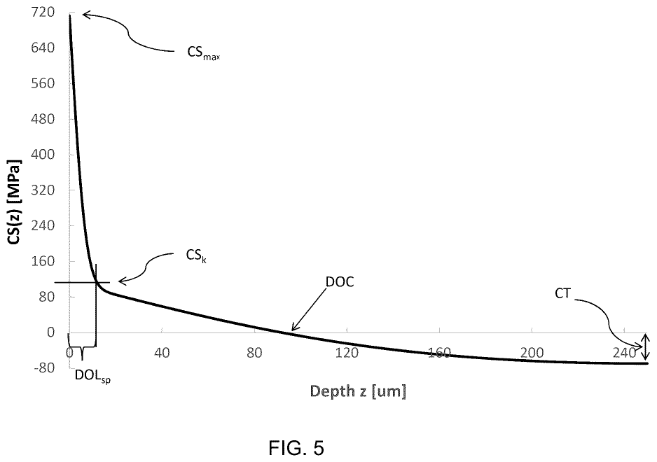

A “knee” of a stress profile is a depth of an article where the slope of the stress profile transitions from steep to gradual. See FIG. 5, for example. The knee may refer to a transition area over a span of depths where the slope is changing. The knee stress CSₖ is defined as the value of compressive stress that the deeper portion of the CS profile extrapolates to at the depth of spike (DOLₛₚ). The DOLₛₚ is reported as measured by a surface-stress meter by known methods. FIG. 5 shows generally a stress profile of compressive stress versus normalized position showing a spike region, a knee, and a tail region; CSmax, CSₖ, DOLₛₚ, and DOC.

The term “Knoop Scratch Threshold” refers to the onset of lateral cracking under specified conditions. In Knoop threshold testing, a mechanical tester holds a Knoop diamond in which a glass is scratched at increasing loads to determine the onset of lateral cracking. As used herein, Knoop Scratch Threshold is the onset of lateral cracking (3 or more of 5 indentation events). In Knoop Scratch Lateral Cracking Threshold testing, samples of the glass articles and articles were first scratched with a Knoop indenter under a dynamic or ramped load to identify the lateral crack onset load range for the sample population. Once the applicable load range is identified, a series of increasing constant load scratches (3 minimum or more per load) are performed to identify the Knoop Scratch Threshold. Knoop Scratch Threshold range can be determined by comparing the test specimen to one of the following 3 failure modes: 1) sustained lateral surface cracks that are more than two times the width of the groove, 2) damage is contained within the groove, but there are lateral surface cracks that are less than two times the width of groove and there is damage visible by naked eye, or 3) the presence of large subsurface lateral cracks which are greater than two times the width of groove and/or there is a median crack at the vertex of the scratch.

### Properties and Attributes—Ranges and Measured Values

Consistent with embodiments, twenty-five exemplary glass compositions were created from melt. The melt input materials for each exemplary composition, determined by weighing, are shown in Table 3.

The “cullet” referenced in Table 3 had the following composition:
greater than or equal to 64.0 mol % and less than or equal to 71.0 mol % SiO₂;
greater than or equal to 9.0 mol % and less than or equal to 12.0 mol % Al₂O₃;
greater than or equal to 6.0 mol % and less than or equal to 11.0 mol % CaO;
greater than or equal to 7.0 mol % and less than or equal to 12.0 mol % B₂O₃;
greater than or equal to 1.0 mol % and less than or equal to 3.0 mol % MgO;
greater than or equal to 0.2 mol % and less than or equal to 2.0 mol % SrO;

In embodiments, as shown in Table 3, the melt input materials were:
greater than or equal to 35.0 wt % and less than or equal to 75 wt % cullet;
greater than or equal to 0.0 wt % and less than or equal to 26 wt % SiO₂;
greater than or equal to 2.0 wt % and less than or equal to 15 wt % Na₂CO₃;
greater than or equal to 10.0 wt % and less than or equal to 22.0 wt % Al₂O₃;
greater than or equal to 4.0 wt % and less than or equal to 12.0 wt % Li₂CO₃.

The compositions of the resultant glass-based compositions are shown in Table 1.

Selected compositions from Table I were subject to various ion-exchange conditions, as described in Table 2. After ion exchange, the following parameters were measured and tabulated in Table 2: CS, DOC, CT, DOC, CsK and KST.

TABLE 1
Exemplary Glass-based Compositions

| | | | | | |
|---|---|---|---|---|---|
| Exemplary Glass | 1 | 2 | 3 | 4 | 5 |

Composition - mol. %

| | | | | | | |
|---|---|---|---|---|---|---|
| SiO₂ | mol. % | 56.79 | 56.11 | 53.44 | 47.22 | 50.76 |
| Al₂O₃ | mol. % | 14.91 | 14.52 | 15.59 | 23.53 | 19.18 |
| Li₂O | mol. % | 4.03 | 10.02 | 9.92 | 10.05 | 10.03 |
| Na₂O | mol. % | 9.57 | 3.91 | 3.95 | 3.98 | 3.94 |
| B₂O₃ | mol. % | 6.38 | 7.29 | 7.79 | 6.91 | 7.20 |
| CaO | mol. % | 6.24 | 6.09 | 6.96 | 6.20 | 6.64 |
| MgO | mol. % | 1.63 | 1.60 | 1.82 | 1.64 | 1.74 |
| SrO | mol. % | 0.38 | 0.38 | 0.43 | 0.38 | 0.41 |
| SnO₂ | mol. % | 0.06 | 0.06 | 0.07 | 0.06 | 0.07 |

Composition constraints

| | | | | | | |
|---|---|---|---|---|---|---|
| Li₂O + Na₂O | mol. % | 13.60 | 13.93 | 13.87 | 14.03 | 13.98 |

Measured properties

| | | | | | | |
|---|---|---|---|---|---|---|
| Density (RT) | g/cm³ | 2.484 | 2.474 | 2.486 | 2.503 | 2.486 |
| RI (@589.3 nm) | | 1.5244 | 1.5327 | 1.5369 | 1.5407 | 1.5366 |
| Young's modulus | GPa | 79.091 | 84.448 | 84.920 | 86.672 | 84.531 |
| Shear Modulus | GPa | 32.095 | 34.215 | 34.261 | 34.741 | 34.031 |
| Poisson's ratio | | 0.23200 | 0.23400 | 0.23900 | 0.24700 | 0.24200 |
| Fracture toughness - K_{ic} | MPa · m^{1/2} | | 0.82000 | 0.87000 | 0.85000 | 0.84000 |
| Strain Point | ° C. | 524 | 502 | 503 | 572 | 531 |
| Annealing Point | ° C. | 564 | 540 | 541 | 614 | 571 |
| Softening Point | ° C. | 755 | 713 | 712 | 794 | 756 |
| Liquidus Temperature | ° C. | 1050 | 1035 | 1030 | 1475 | 1105 |
| Liquidus viscosity | Poise | 15631 | 7396 | 5570 | 51 | 2929 |

| Exemplary Glass | | 6 | 7 | 8 |
|---|---|---|---|---|
| Composition - mol. % | | | | |
| SiO₂ | mol. % | 52.34 | 51.68 | 48.05 |
| Al₂O₃ | mol. % | 17.27 | 17.27 | 22.63 |
| Li₂O | mol. % | 9.96 | 10.87 | 9.93 |
| Na₂O | mol. % | 3.94 | 3.91 | 4.01 |
| B₂O₃ | mol. % | 7.52 | 7.31 | 7.02 |
| CaO | mol. % | 6.71 | 6.70 | 6.24 |
| MgO | mol. % | 1.75 | 1.75 | 1.66 |
| SrO | mol. % | 0.41 | 0.41 | 0.38 |
| SnO₂ | mol. % | 0.07 | 0.07 | 0.06 |
| Composition constraints | | | | |
| Li₂O + Na₂O | mol. % | 13.90 | 14.79 | 13.94 |
| Measured properties | | | | |
| Density (RT) | g/cm³ | 2.485 | 2.488 | 2.497 |
| RI (@589.3 nm) | | 1.537 | 1.5377 | 1.5397 |
| Young's modulus | GPa | 84.149 | 85.050 | 85.749 |
| Shear Modulus | GPa | 33.873 | 34.318 | 34.430 |
| Poisson's ratio | | 0.24200 | 0.23900 | 0.24500 |
| Fracture toughness - K_{ic} | MPa · m^{1/2} | 0.79000 | 0.83000 | 0.83000 |
| Strain Point | ° C. | 519 | 508 | 567 |
| Annealing Point | ° C. | 559 | 546 | 608 |
| Softening Point | ° C. | 733 | 721 | 791 |
| Liquidus Temperature | ° C. | 1060 | 1045 | 1335 |
| Liquidus viscosity | Poise | 4020 | 4155 | 155 |

| | | | | | |
|---|---|---|---|---|---|
| Exemplary Glass | 9 | 10 | 11 | 12 | 13 |

Composition - mol. %

| | | | | | | |
|---|---|---|---|---|---|---|
| SiO₂ | mol. % | 48.67 | 49.56 | 50.26 | 50.14 | 47.41 |
| Al₂O₃ | mol. % | 21.81 | 20.84 | 19.94 | 19.12 | 22.75 |
| Li₂O | mol. % | 9.94 | 9.85 | 9.85 | 10.74 | 10.92 |
| Na₂O | mol. % | 4.00 | 4.00 | 3.98 | 3.99 | 3.96 |
| B₂O₃ | mol. % | 7.08 | 7.19 | 7.32 | 7.27 | 6.83 |
| CaO | mol. % | 6.35 | 6.40 | 6.47 | 6.54 | 6.07 |
| MgO | mol. % | 1.68 | 1.69 | 1.72 | 1.73 | 1.63 |
| SrO | mol. % | 0.39 | 0.40 | 0.40 | 0.40 | 0.37 |
| SnO₂ | mol. % | 0.06 | 0.07 | 0.07 | 0.07 | 0.06 |

Composition constraints

| | | | | | | |
|---|---|---|---|---|---|---|
| Li₂O + Na₂O | mol. % | 13.94 | 13.84 | 13.83 | 14.72 | 14.87 |

Measured properties

| | | | | | | |
|---|---|---|---|---|---|---|
| Density (RT) | g/cm³ | 2.493 | 2.493 | 2.487 | 2.488 | 2.498 |
| RI (@589.3 nm) | | 1.5392 | 1.5387 | 1.5372 | 1.5376 | 1.5406 |
| Young's modulus | GPa | 84.958 | 84.562 | 84.193 | 84.606 | 86.045 |
| Shear Modulus | GPa | 34.161 | 34.061 | 33.907 | 34.095 | 34.581 |
| Poisson's ratio | | 0.24300 | 0.24100 | 0.24200 | 0.24100 | 0.24400 |
| Fracture toughness - K_{ic} | | 0.85 | 0.83 | 0.85 | 0.78 | 0.89 |
| Strain Point | ° C. | 557 | 548 | 544 | 517 | 560 |
| Annealing Point | ° C. | 598 | 588 | 585 | 556 | 600 |
| Softening Point | ° C. | 785 | 776 | 766 | 744 | 779 |
| Liquidus Temperature | ° C. | 1330 | 1180 | 1125 | 1085 | 1350 |
| Liquidus viscosity | Poise | 173 | 968 | 2115 | 2647 | 116 |

| Exemplary Glass | | 14 | 15 | 16 |
|---|---|---|---|---|
| Composition - mol. % | | | | |
| SiO₂ | mol. % | 56.90 | 56.80 | 58.15 |
| Al₂O₃ | mol. % | 22.34 | 21.39 | 20.71 |
| Li₂O | mol. % | 9.99 | 11.04 | 9.94 |
| Na₂O | mol. % | 2.05 | 2.04 | 2.04 |
| B₂O₃ | mol. % | 3.98 | 3.98 | 4.15 |
| CaO | mol. % | 3.54 | 3.54 | 3.74 |
| MgO | mol. % | 0.95 | 0.95 | 1.00 |
| SrO | mol. % | 0.22 | 0.22 | 0.23 |
| SnO₂ | mol. % | 0.03 | 0.04 | 0.04 |
| Composition constraints | | | | |
| Li₂O + Na₂O | mol. % | 12.03 | 13.08 | 11.98 |
| Measured properties | | | | |
| Density (RT) | g/cm³ | 2.470 | 2.461 | 2.458 |
| RI (@589.3 nm) | | 1.5326 | 1.5318 | 1.5301 |
| Young's modulus | GPa | 87.123 | 86.070 | 85.869 |
| Shear Modulus | GPa | 35.318 | 34.871 | 34.824 |
| Poisson's ratio | | 0.23300 | 0.23400 | 0.23300 |
| Fracture toughness - K_{ic} | | 0.84 | 0.84 | 0.82 |
| Strain Point | ° C. | 624 | 614 | 617 |
| Annealing Point | ° C. | 668 | 659 | 661 |
| Softening Point | ° C. | 866 | 860 | 870 |
| Liquidus Temperature | ° C. | 1440 | 1390 | 1450 |
| Liquidus viscosity | Poise | 168 | 279 | 177 |

| | | | | | |
|---|---|---|---|---|---|
| Exemplary Glass | 17 | 18 | 19 | 20 | 21 |

Composition - mol. %

| | | | | | | |
|---|---|---|---|---|---|---|
| SiO₂ | mol. % | 58.04 | 56.46 | 57.94 | 57.94 | 58.10 |
| Al₂O₃ | mol. % | 19.73 | 20.22 | 18.38 | 17.89 | 18.11 |
| Li₂O | mol. % | 11.02 | 11.04 | 10.98 | 10.97 | 10.92 |
| Na₂O | mol. % | 2.04 | 2.03 | 2.02 | 2.02 | 2.02 |
| B₂O₃ | mol. % | 4.15 | 4.64 | 4.84 | 6.02 | 5.72 |
| CaO | mol. % | 3.75 | 4.18 | 4.35 | 3.85 | 3.83 |
| MgO | mol. % | 1.00 | 1.12 | 1.17 | 1.02 | 1.02 |
| SrO | mol. % | 0.23 | 0.26 | 0.27 | 0.24 | 0.24 |
| SnO₂ | mol. % | 0.04 | 0.04 | 0.04 | 0.04 | 0.04 |

Composition constraints

| | | | | | | |
|---|---|---|---|---|---|---|
| Li₂O + Na₂O | mol. % | 13.06 | 13.07 | 13.00 | 12.99 | 12.94 |

Measured properties

| | | | | | | |
|---|---|---|---|---|---|---|
| Density (RT) | g/cm³ | 2.449 | 2.457 | 2.447 | 2.431 | 2.433 |
| RI (@589.3 nm) | | 1.5291 | 1.531 | 1.5288 | 1.5265 | 1.5262 |
| Young's modulus | GPa | 84.579 | 84.766 | 83.403 | 81.900 | 82.364 |
| Shear Modulus | GPa | 34.277 | 34.312 | 33.858 | 33.292 | 33.454 |
| Poisson's ratio | | 0.23400 | 0.23500 | 0.23200 | 0.23000 | 0.23100 |
| Fracture toughness - K_{ic} | | 0.81000 | 0.85000 | 0.85000 | 0.87000 | 0.83000 |
| Strain Point | ° C. | 603 | 599 | 580 | 567 | 573 |
| Annealing Point | ° C. | 646 | 643 | 623 | 611 | 618 |
| Softening Point | ° C. | 852 | 848 | 829 | 819 | 821 |
| Liquidus Temperature | ° C. | 1365 | 1380 | 1200 | 1185 | 1190 |
| Liquidus viscosity | Poise | 437 | 276 | 2,677 | 3,306 | 3,524 |

| Exemplary Glass | | 22 | 23 | 24 | 25 |
|---|---|---|---|---|---|
| Composition - mol. % | | | | | |
| SiO₂ | mol. % | 58.22 | 58.08 | 57.92 | 49.73 |
| Al₂O₃ | mol. % | 18.75 | 19.12 | 19.66 | 21.49 |
| Li₂O | mol. % | 10.92 | 10.94 | 10.98 | 10.85 |
| Na₂O | mol. % | 2.00 | 2.01 | 2.00 | 2.04 |
| B₂O₃ | mol. % | 4.97 | 4.71 | 4.28 | 7.25 |
| CaO | mol. % | 3.84 | 3.82 | 3.85 | 6.47 |
| MgO | mol. % | 1.02 | 1.03 | 1.02 | 1.71 |
| SrO | mol. % | 0.24 | 0.24 | 0.24 | 0.40 |
| SnO₂ | mol. % | 0.04 | 0.04 | 0.04 | 0.07 |
| Composition constraints | | | | | |
| Li₂O + Na₂O | mol. % | 12.92 | 12.95 | 12.98 | 12.88 |
| Measured properties | | | | | |
| Density (RT) | g/cm³ | 2.441 | 2.445 | 2.453 | 2.490 |
| RI (@589.3 nm) | | 1.5278 | 1.5288 | 1.5297 | 1.5408 |
| Young's modulus | GPa | 83.079 | 83.931 | 84.425 | 85.726 |
| Shear Modulus | GPa | 33.715 | 33.978 | 34.339 | 34.509 |
| Poisson's ratio | | 0.23200 | 0.23500 | 0.22900 | 0.24200 |
| Fracture toughness - K_{ic} | | 0.83000 | 0.84000 | 0.84000 | 0.82000 |
| Strain Point | ° C. | 584 | 591 | 597 | 565 |
| Annealing Point | ° C. | 627 | 635 | 642 | 606 |
| Softening Point | ° C. | 834 | 844 | 846 | 792 |
| Liquidus Temperature | ° C. | 1300 | 1300 | 1335 | 1365 |
| Liquidus viscosity | Poise | 780 | 838 | 556 | 109 |

TABLE 2
IOX results from 450° C. 80% KNO₃ and 20% NaNO₃ Bath

| | IOX | | CS (MPa) | DOL (um) | CT (MPa)- | DOC (um) | CSk(MPa)- | |
|---|---|---|---|---|---|---|---|---|
| | conditions | | SWL-365 | RNF | SCALP210 | from RNF | RNF | KST |
| Composition #10 | 8 | hours | 949 | 4.7 | 102 | 124 | 400 | 4-6N |
| 0.8 mm | 12 | hours | 868 | 4.3 | 123 | 148 | 302 | 6-8N |
| | 16 | hours | 840 | 5.0 | 142 | 161 | 300 | 4-6N |
| | 20 | hours | 774 | 6.1 | 153 | 167 | 279 | 2-4N |
| Composition #11 | 8 | hours | 868 | 4.5 | 101 | 127 | 365 | 6-8N |
| 0.8 mm | 12 | hours | 860 | 5.0 | 124 | 152 | 301 | 4-6N |
| | 16 | hours | 781 | 5.8 | 133 | 166 | 254 | 6-8N |
| | 20 | hours | 733 | 6.5 | 143 | 173 | 237 | 2-4N |
| Composition #12 | 8 | hours | 783 | 4.5 | 97 | 125 | 364 | 4-6N |
| 0.8 mm | 12 | hours | 789 | 5.6 | 115 | 150 | 261 | 4-6N |
| | 16 | hours | 721 | 6.7 | 121 | 160 | 238 | 4-6N |
| | 20 | hours | 662 | 8.6 | 134 | 169 | 215 | 2-4N |
| Composition #19 | 8 | hours | 788 | 5.4 | 165 | 168 | 337 | 8-10N |
| 0.8 mm | 12 | hours | 715 | 6.4 | 184 | 183 | 270 | 8-10N |
| | 16 | hours | 666 | 7.9 | 182 | 191 | 225 | 4-6N |
| Composition #20 | 8 | hours | 728 | 6.1 | 156 | 171 | 265 | 12-14N |
| 0.8 mm | 12 | hours | 665 | 7.98 | 169 | 184 | 209 | 2-4N |
| | 16 | hours | 625 | 9.4 | 160 | 189 | 176 | 8-10N |
| Composition #21 | 8 | hours | 748 | 6 | 165 | 170 | 287 | 4-6N |
| 0.8 mm | 12 | hours | 676 | 7.8 | 175 | 184 | 227 | 8-10N |
| | 16 | hours | 641 | 9 | 162 | 189 | 188 | 10-12N |

TABLE 3
Percentage of recycled content in each glass

| Exemplary Glass | 1 | 2 | 3 | 4 | 5 | 6 | 7 | 8 | 9 |
|---|---|---|---|---|---|---|---|---|---|
| wt % of cullet | 63.6 | 65.4 | 73.3 | 62.0 | 68.1 | 70.7 | 69.7 | 63.2 | 64.4 |
| wt % of SiO₂ | 7.5 | 7.8 | | | | | | | |
| wt % of Na₂CO₃ | 14.8 | 6.1 | 6.0 | 5.8 | 5.9 | 6.0 | 6.0 | 5.8 | 5.8 |
| wt % of Al₂O₃ | 10.0 | 10.2 | 10.2 | 22.2 | 15.6 | 12.9 | 12.9 | 20.9 | 19.6 |
| wt % of Li₂CO₃ | 4.1 | 10.6 | 10.5 | 10.0 | 10.3 | 10.4 | 11.4 | 10.1 | 10.1 |
| Exemplary Glass | 10 | 11 | 12 | 13 | 14 | 15 | 16 | 17 | 18 |
| wt % of cullet | 65.6 | 66.9 | 67.1 | 61.6 | 36.2 | 36.4 | 38.4 | 38.6 | 43.0 |
| wt % of SiO₂ | | | | | 25.1 | 25.2 | 25.3 | 25.4 | 21.1 |
| wt % of Na₂CO₃ | 5.9 | 5.9 | 5.9 | 5.8 | 2.9 | 3.0 | 3.0 | 3.0 | 3.0 |
| wt % of Al₂O₃ | 18.3 | 17.0 | 15.6 | 21.5 | 25.5 | 24.2 | 22.9 | 21.6 | 21.5 |
| wt % of Li₂CO₃ | 10.2 | 10.3 | 11.3 | 11.1 | 10.3 | 11.3 | 10.4 | 11.5 | 11.4 |

| Exemplary Glass | 19 | 20 | 21 | 22 | 23 | 24 | 25 |
|---|---|---|---|---|---|---|---|
| wt % of cullet | 45.3 | 39.8 | 39.8 | 39.7 | 39.6 | 39.5 | 66.6 |
| wt % of SiO₂ | 21.3 | 25.0 | 24.9 | 24.8 | 24.8 | 24.8 | |
| wt % of Na₂CO₃ | 3.0 | 3.0 | 3.0 | 3.0 | 3.0 | 3.0 | 2.9 |
| wt % of Al₂O₃ | 18.8 | 18.9 | 19.3 | 20.2 | 20.7 | 21.3 | 19.1 |
| wt % of Li₂CO₃ | 11.5 | 11.6 | 11.5 | 11.5 | 11.5 | 11.5 | 11.3 |
| wt % of B₂O₃ | | 1.8 | 1.5 | 0.8 | 0.4 | | |

The glass-based compositions described herein use as input to the melt a significant amount of cullet that is tailored for purposes other than ion-exchanged glass-based materials for use in mobile consumer electronics. Notwithstanding that fact, the glass-based compositions described herein have liquidus viscosities that are compatible with thin sheet rolling, an existing forming method, so it is manufacturable. And, the glass-based compositions described herein are ion exchangeable, and have favorable attributes such as Knoop Stress Threshold (KST), DOC and fracture toughness (K_{1C}).

According to embodiments, the glass composition may have a liquidus temperature of greater than or equal to 500 C, or greater than or equal to 1000 C. The liquidus temperature may be 500 C, 1000 C, 1050 C, 1100 C, 1150 C, 1200 C, 1250 C, 1300 C, 1350 C, 1400 C, 1450 C, 1500 C, and any range having any two of these values as endpoints. In preferred embodiments, the liquidus temperature is greater than or equal to 1000 C and less than or equal to 1500 C; greater than or equal to 1050 C and less than or equal to 1450 C; or greater than or equal to 1100 C and less than or equal to 1400 C.

According to embodiments, the glass composition may have a Knoop Scratch Threshold (KST) of greater than or equal to 4 N and less than or equal to 12 N. The liquidus temperature may be 4 N, 5 N, 6 N, 7 N, 8 N, 9 N, 10 N, 11 N, 12 N, and any range having any two of these values as endpoints. In preferred embodiments, the liquidus temperature is greater than or equal to 4 N and less than or equal to 12 N; greater than or equal to 5 N and less than or equal to 11 N; or greater than or equal to 6 N and less than or equal to 10 N.

According to embodiments, the glass composition may have a fracture toughness (K_{1C}) of greater than or equal to 0.80 MPa(m)^{1/2} and less than or equal to 0.90 MPa(m)^{1/2}. The fracture toughness may be 0.80 MPa(m)^{1/2}, 0.81 MPa(m)^{1/2}, 0.82 MPa(m)^{1/2}, 0.83 MPa(m)^{1/2}, 0.84 MPa(m)^{1/2}, 0.85 MPa(m)^{1/2}, 0.86 MPa(m)^{1/2}, 0.87 MPa(m)^{1/2}, 0.88 MPa(m)^{1/2}, 0.89 MPa(m)^{1/2}, 0.90 MPa(m)^{1/2}, and any range having any two of these values as endpoints. In preferred embodiments, the liquidus temperature is greater than or equal to 0.80 MPa(m)^{1/2} and less than or equal to 0.90 MPa(m)^{1/2}, greater than or equal to 0.81 MPa(m)^{1/2} and less than or equal to 0.89 MPa(m)^{1/2}, or greater than or equal to 0.82 MPa(m)^{1/2} and less than or equal to 0.88 MPa(m)^{1/2}.

### Ion Exchange

Compressive stress layers may be formed in the glass by exposing the glass to an ion exchange solution. In embodiments, the ion exchange solution may be molten nitrate salts or molten sulfate salts. In embodiments, the ion exchange solution may be molten KNO₃, molten NaNO₃, or combinations thereof. In certain embodiments, the ion exchange solution may comprise 80% molten KNO₃ and 20% NaNO₃.

The glass composition may be exposed to the ion exchange solution by dipping a glass article made from the glass composition into a bath of the ion exchange solution, spraying the ion exchange solution onto a glass article made from the glass composition, or otherwise physically applying the ion exchange solution to a glass article made from the glass composition. Upon exposure to the glass composition, the ion exchange solution may, according to embodiments, be at a temperature from greater than or equal to 380° C. to less than or equal to 470° C., such as from greater than or equal to 385° C. to less than or equal to 455° C., from greater than or equal to 400° C. to less than or equal to 465° C., from greater than or equal to 420° C. to less than or equal to 460° C., or from greater than or equal to 440° C. to less than or equal to 455° C. In embodiments, the glass composition may be exposed to the ion exchange solution for a duration from greater than or equal to 6 hour to less than or equal to 20 hours, such as from greater than or equal to 8 hours to less than or equal to 16 hours, or from greater than or equal to 10 hours to less than or equal to 14 hours.

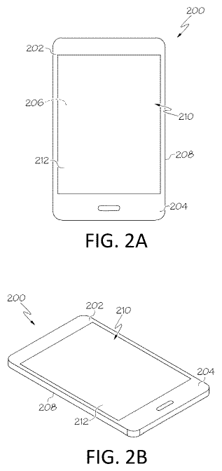

The glass articles made from the glass compositions disclosed herein may be incorporated into another article, for example an article with a display (or display articles) (e.g., consumer electronics, including mobile phones, watches, tablets, computers, navigation systems, and the like), architectural articles, transportation articles (e.g., automobiles, trains, aircraft, sea craft, etc.), appliance articles, or any article that may benefit from some transparency, scratch-resistance, abrasion resistance or a combination thereof. An exemplary article incorporating any of the glass articles disclosed herein is shown in FIGS. 2A and 2B. Specifically, FIGS. 2A and 2B shows a consumer electronic product 200 including a housing 202 having a front surface 204, a back surface 206, and side surfaces 208. A display 210, for example, a light emitting diode (LED) display or an organic light emitting diode (OLED) display, is at least partially inside the housing 202. A cover substrate 212 may be disposed at or over front surface 204 of housing 202 such that it is disposed over display 210. Cover substrate 212 may include any of the glass articles made from the glass compositions disclosed herein. Cover substrate 212 may serve to protect display 210 and other components of consumer electronic product 200 from damage. In embodiments, cover substrate 212 may be bonded to display 210 with an adhesive. In embodiments, cover substrate 212 may define all or a portion of front surface 204 of housing 202. In some embodiments, cover substrate 212 may define front surface 204 of housing 202 and all or a portion of side surfaces 208 of housing 202.

### Examples

Embodiments will be further clarified by the following examples. It should be understood that these examples are not limiting to the embodiments described above.

Example 1: Input materials for a melt were measured by weight (wt %) as described in Table 3, and used as input to a melt. The melt was processed into sheets using thin sheet rolling.

Example 2: The sheets produced in Example 1 were analyzed to determine the composition of the glass-based materials in mol %. The results are shown in Table 1. Various attributes of the glass-based materials were measured, and are also shown in Table 1.

Example 3: sheets of selected compositions, specifically Compositions 10, 11, 12, 19, 20 and 21, were ion-exchanged under the conditions shown in Table 2. Various attributes of the ion-exchanged sheets were measured, and are also shown in Table 2.

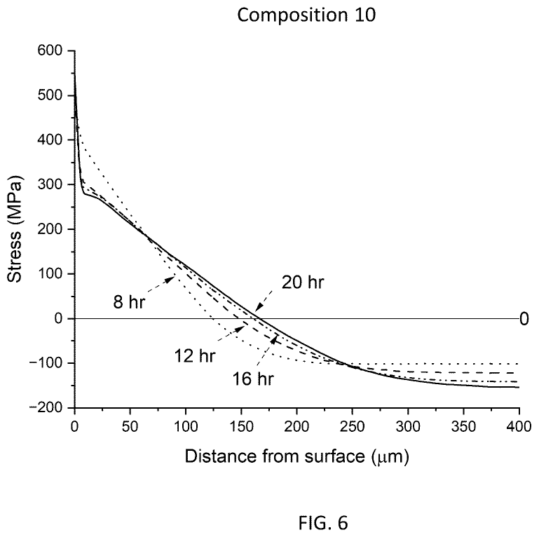

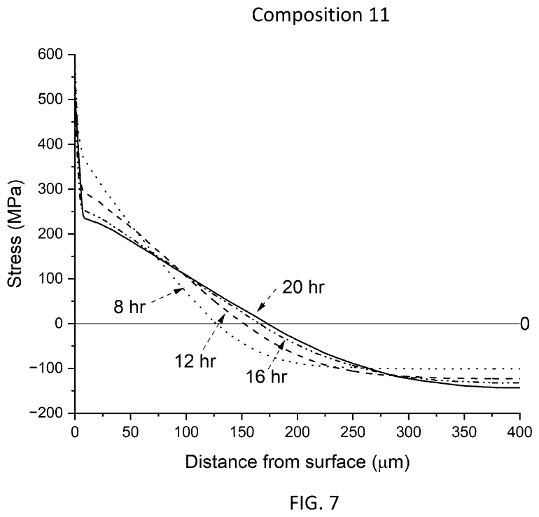

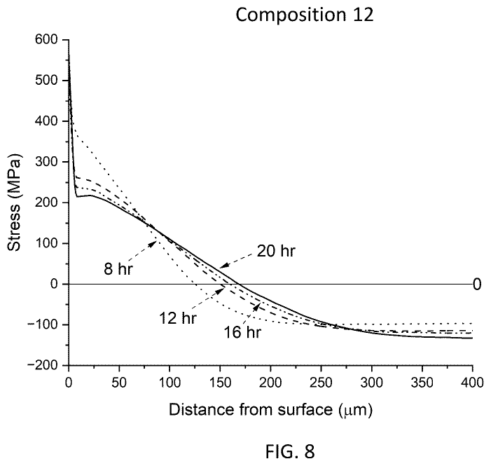

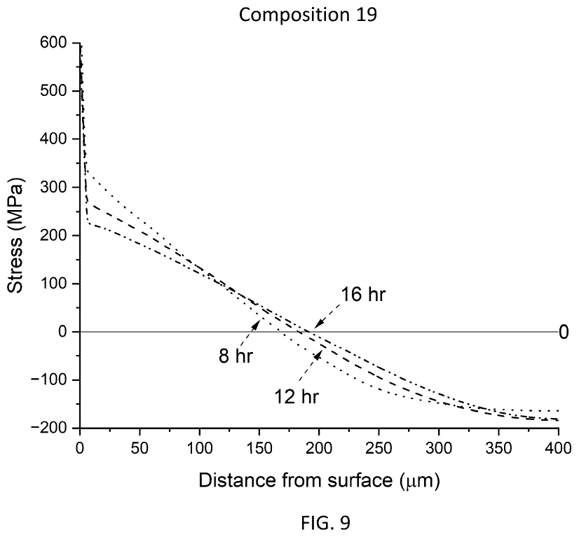

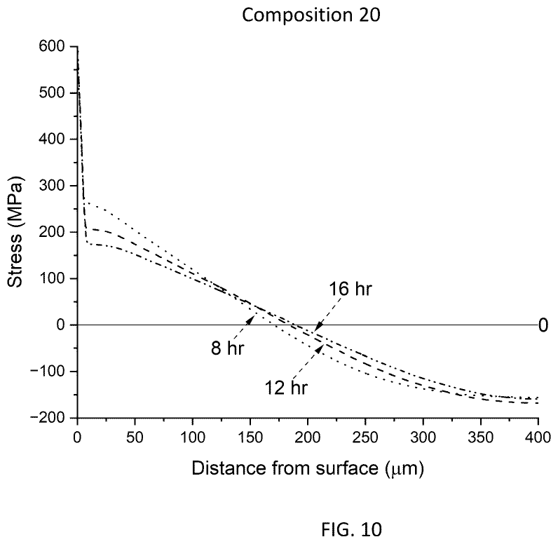

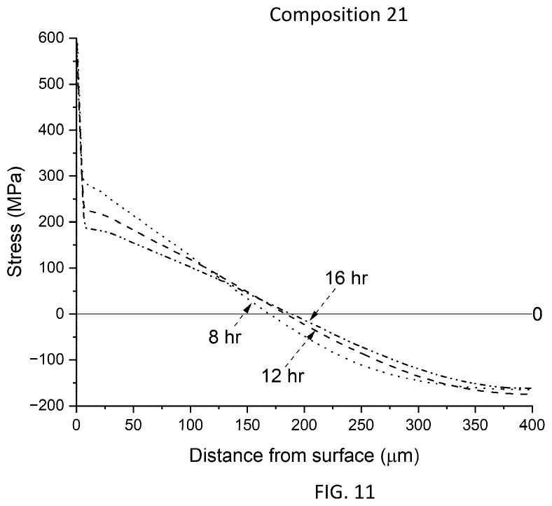

FIGS. 6, 7, 8, 9, 10 and 11 are graphs showing the stress profiles as measured after various IOX conditions, including different IOX times, for Compositions 10, 11, 12, 19, 20 and 21, respectively.

All compositional components, relationships, and ratios described in this specification are provided in mol % unless otherwise stated. All ranges disclosed in this specification include any and all ranges and subranges encompassed by the broadly disclosed ranges whether or not explicitly stated before or after a range is disclosed.

It will be apparent to those skilled in the art that various modifications and variations can be made to the implementations described herein without departing from the spirit and scope of the claimed subject matter. Thus, it is intended that the specification cover the modifications and variations of the various implementations described herein provided such modification and variations come within the scope of the appended claims and their equivalents.

What is claimed is:

1. A glass-based article, comprising:
greater than or equal to 45.0 mol % and less than or equal to 60.0 mol % SiO₂;
greater than or equal to 10.0 mol % and less than or equal to 25.0 mol % Al₂O₃;
greater than or equal to 2.0 mol % and less than or equal to 8.0 mol % CaO;
greater than or equal to 2.0 mol % and less than or equal to 10.0 mol % B₂O₃;
greater than or equal to 0.2 mol % and less than or equal to 3.0 mol % MgO;
greater than or equal to 0.2 mol % and less than or equal to 1.0 mol % SrO;
greater than or equal to 0.0 mol % and less than or equal to 15.0 mol % Li₂O;
greater than or equal to 0.0 mol % and less than or equal to 10.0 mol % Na₂O;
greater than or equal to 10.0 mol % and less than or equal to 25.0 mol % Li₂O+Na₂O;
wherein the ratio CaO (mol %)/MgO (mol %) is greater than or equal to 2.

2. The glass-based article of claim 1, further comprising:
greater than or equal to 50.0 mol % and less than or equal to 58.0 mol % SiO₂.

3. The glass-based article of claim 1, further comprising:
greater than or equal to 14.0 mol % and less than or equal to 23.0 mol % Al₂O₃.

4. The glass-based article of claim 1, further comprising:
greater than or equal to 3.0 mol % and less than or equal to 7.0 mol % CaO.

5. The glass-based article of claim 1, further comprising:
greater than or equal to 4.0 mol % and less than or equal to 8.0 mol % B₂O₃.

6. The glass-based article of claim 1, further comprising:
greater than or equal to 0.9 mol % and less than or equal to 1.8 mol % MgO.

7. The glass-based article of claim 1, further comprising:
greater than or equal to 0.2 mol % and less than or equal to 0.5 mol % SrO.

8. The glass-based article of claim 1, further comprising:
greater than or equal to 4.0 mol % and less than or equal to 12.0 mol % Li₂O.

9. The glass-based article of claim 1, further comprising:
greater than or equal to 2.0 mol % and less than or equal to 9.0 mol % Na₂O.

10. The glass-based article of claim 1, further comprising:
greater than or equal to 11.0 mol % and less than or equal to 15.0 mol % Li₂O+Na₂O.

11. The glass-based article of claim 1, wherein the glass-based article has a K_{1C} fracture toughness as measured by a chevron notch short bar method of greater than or equal to 0.8.

12. The glass-based article of claim 1, wherein the glass-based article has a liquidus viscosity of greater than or equal to 1000 poise.

13. The glass-based article of claim 1, wherein the glass-based article has an anorthite liquidus phase.

14. The glass-based article of claim 1, wherein the glass-based article is chemically strengthened and has a compressive stress of greater than or equal to 550.0 MPa.

15. The glass-based article of claim 1, wherein the strengthened glass-based article has a maximum central tension of greater than or equal to 90.0 MPa.

16. The glass-based article of claim 1, wherein the strengthened glass-based article has a depth of compression (DOC) greater than or equal to 160.0 microns.

17. The glass-based article of claim 1, wherein the strengthened glass-based article has a Knoop Scratch threshold in the range of greater than or equal to 4.0 N to less than or equal to 14.0 N.

18. A process for making a glass-based material, comprising:
creating a melt, the melt comprising:
greater than or equal to 35.0 wt % and less than or equal to 75 wt % cullet;
greater than or equal to 0.0 wt % and less than or equal to 26 wt % SiO₂;
greater than or equal to 2.0 wt % and less than or equal to 15 wt % Na₂CO₃;
greater than or equal to 10.0 wt % and less than or equal to 22.0 wt % Al₂O₃;
greater than or equal to 4.0 wt % and less than or equal to 12.0 wt % Li₂CO₃;
processing the melt to form a glass-based material;
wherein the cullet comprises:
greater than or equal to 64.0 mol % and less than or equal to 71.0 mol % SiO₂;
greater than or equal to 9.0 mol % and less than or equal to 12.0 mol % Al₂O₃;
greater than or equal to 6.0 mol % and less than or equal to 11.0 mol % CaO;
greater than or equal to 7.0 mol % and less than or equal to 12.0 mol % B₂O₃;
greater than or equal to 1.0 mol % and less than or equal to 3.0 mol % MgO;
greater than or equal to 0.2 mol % and less than or equal to 2.0 mol % SrO; and
wherein the glass-based material comprises the composition of the glass-based article of claim 1.

19. The process of claim 18, wherein processing the melt comprises forming the melt into a sheet using a thin sheet rolling process.

20. A consumer electronic device, comprising:
a housing having a front surface, a back surface, and side surfaces;
electrical components provided at least partially with the housing, the electrical components including at least a controller, a memory, and a display, the display being provided at or adjacent the front surface of the housing; and
a glass-based article according to claim 1 disposed over the display.
